(19) United States
(12) Patent Application Publication
(10) Pub. No.: US 2010/0307796 A1
(43) Pub. Date: Dec. 9, 2010

(54) Method for Selective Adsorption of Noble Metal Onto Surface of Polymer

(75) Inventor: Hong Kee LEE, Goyang-si (KR)

Correspondence Address: KNOBBE MARTENS OLSON & BEAR LLP, 2040 MAIN STREET, FOURTEENTH FLOOR, IRVINE, CA, 92614, US

(73) Assignee: KOREA INSTITUTE OF INDUSTRIAL TECHNOLOGY, Cheonan-si (KR)

(21) Appl. No.: 12/845,656

(22) Filed: Jul. 28, 2010

Related U.S. Application Data
(63) Continuation of application No. PCT/KR2009/000384, filed on Jan. 23, 2009.

(30) Foreign Application Priority Data
Jan. 28, 2008 (KR) 10-2008-0008626

(51) Int. Cl. H05K 1/00; G03F 7/20; B32B 3/10; B32B 15/08

(52) U.S. Cl. 174/250; 430/325; 430/319; 428/209

(57) ABSTRACT

The present disclosure relates to a method for the selective adsorption of a noble metal catalyst onto a surface of a polymer. More particularly, the method of the present invention includes a first step of masking with a photo mask, the surface of a polymer adsorbed with a photosensitive metal ion, and radiating light onto the surface of the polymer such that the photosensitive metal ion on the unmasked surface is oxidized, and a second step of permitting the photosensitive metal ion which is not oxidized in the first step to react to a noble metal catalyst such that the noble metal catalyst is adsorbed onto the surface of the polymer.

### CROSS REFERENCE TO RELATED APPLICATIONS

This application is a continuation application under 35 U.S.C. §365(c) of International Patent Application No. PCT/KR2009/000384, filed Jan. 23, 2009, designating the United States, which claims for the benefit of earlier filing date under 35 U.S.C. §365(b) of Korean Patent Application No. 10-2008-0008626, filed Jan. 28, 2008. International Application No. PCT/KR2009/000384 was published in Korean as WO 2009/096691 A1 on Aug. 6, 2009. This application incorporates herein by reference the International Application No. PCT/KR2009/000384 and the Korean Patent Application No. 10-2008-0008626 in their entirety.

### TECHNICAL FIELD

The present invention relates to a method of selectively adsorbing a precious metal on polymer surface. A polymer film including a metal layer having a predetermined form can be manufactured using the method.

### BACKGROUND

Currently, as a technology for forming a metal circuit pattern on a polymer material such as polyimide (PI), polyethylene terephthalate (PET) or the like, which is used as a dielectric for flexible circuit boards or packages, a method of forming a metal circuit pattern by forming a predetermined circuit pattern on the surface of a polymer clad or deposited with thin copper foil using photoresist processing and then etching the copper foil is widely used.

Such a conventional technology used to form a metal circuit pattern is problematic in that it is complicated, it includes long unit processes, it needs high-priced equipment, and it causes environmental pollution due to the formation of a corrosive etching solution. Further, this conventional technology used to form a metal circuit pattern is problematic in that cheap raw materials and expensive precise equipment are additionally required to realize a micro-circuit pattern or it is very difficult to realize the micro-circuit pattern.

Meanwhile, methods of forming a metal layer on a polymer material are conducted by a laminating or casting process. In the laminating or casting process, a polymer material is surface-modified by plasma ions, and then a conductive metal junction layer is formed on the surface of the surface-modified polymer material using a dry surface treatment technology such as sputtering, metal deposition or the like, and then a metal coating layer is formed on the surface of the conductive metal junction layer using an electroplating technology or a copper film is directly bonded to the surface of the polymer material.

Recently, a process of metalizing a polymer film using wet surface treatment has been developed. In this process, a metal circuit is also formed by forming a metal layer on a polymer material and then etching the metal layer with copper using photoresist processing. However, this process is also problematic in that it is not easy to form a relatively uniform metal layer, and in that high production expenses are incurred.

### SUMMARY

An aspect of the present invention is to provide a method of selectively adsorbing a precious metal on polymer surface.

Another aspect of the present invention is to provide a polymer film including a metal layer formed by wet-plating the polymer on which the precious metal is selectively adsorbed using the method.

The polymer adsorbed with the precious metal, prepared according to embodiments of the present invention, is advantageous in that various shapes of metal pattern layers can be simply and easily formed on the surface thereof, and a metal circuit layer made of copper, nickel or the like adheres closely to the surface thereof, and thus it can be easily used in automobiles, electronics, communications and semiconductors requiring micro-circuit boards. Further, when the polymer is prepared according to embodiments the present invention, there is an advantage in that the manufacturing cost thereof becomes low compared to conventional technologies, and expensive equipment is not required.

### BRIEF DESCRIPTION OF DRAWINGS

FIG. 1 is a process view showing a method of selectively adsorbing a precious metal on the surface of a polymer adsorbed with photosensitive metal ions according to an embodiment of the present invention;

FIG. 2 is a graph showing the changes in the chemical structure of tin (Sn) ions by a photochemical reaction using X-ray photoelectron spectroscopy (XPS) after UV irradiation according to an embodiment of the present invention; and

FIG. 3 is a graph showing the results of the adsorption of a precious metal (for example, Pd^{o}) using X-ray photoelectron spectroscopy (XPS) after UV irradiation according to an embodiment of the present invention.

### DETAILED DESCRIPTION OF EMBODIMENTS

The present inventors have developed a method of adsorbing a precious metal on a polymer film during wet surface treatment.

One aspect of the present invention is directed to a method of selectively adsorbing a precious metal or precious metal catalyst on the surface of a polymer. More specifically, one embodiment of the present invention is directed to a method of selectively adsorbing a precious metal catalyst on polymer surface, including the steps of: 1) masking the surface of a polymer adsorbed with photosensitive metal ions with a photomask and then irradiating the surface of the polymer with a light source to oxidize the photosensitive metal ions which are on the non-masked surface of the polymer; and 2) reacting the photosensitive metal ions not oxidized in step 1) with a precious metal catalyst to adsorb the precious metal catalyst on the surface of the polymer.

The polymer used in embodiments of the present invention includes polyimide, polyethylene terephthalate (PET) and aramid film, although not limited thereto, and is used to fabricate a flexible copper clad laminate (FCCL) which is an intermediate material used in a flexible printed circuit board (FPCB), to form an electronic circuit pattern or to prevent electromagnetic interference (EMI). It is preferred that the polymer used in embodiments of the present invention be a polymer adsorbed with photosensitive metal ions.

The photosensitive metal ions are metal ions causing a photochemical reaction using a light source, and, for example, include titanium (Ti) ions, molybdenum (Mo) ions, tungsten (W) ions and tin (Sn) ions, although not limited thereto. In embodiments of the present invention, a polymer whose surface is adsorbed with tin ions is used as the polymer. The method of adsorbing the photosensitive metal ions on the surface of the polymer may be conducted using the methods well known in the related field, preferably, the method disclosed in Korea Patent Application No. 2007-0003316, filed by the present inventors.

More specifically, the method of adsorbing the photosensitive metal ions on the surface of the polymer may include the steps of: immersing the surface of the polymer into an alkali metal compound solution (for example, alkali metal hydroxide, alkali earth metal hydroxide or the like) or spraying the alkali metal compound solution onto the surface of the polymer to hydrophilize the surface of the polymer; providing functional groups onto the surface of the polymer to modify the surface of the polymer; and immersing the modified surface of the polymer into a solution containing photosensitive metal ions or spraying the solution onto the modified surface of the polymer.

The precious metal catalyst used in embodiments of the present invention is, for example, silver (Ag), palladium (Pd), platinum (Pt), gold (Au) or the like.

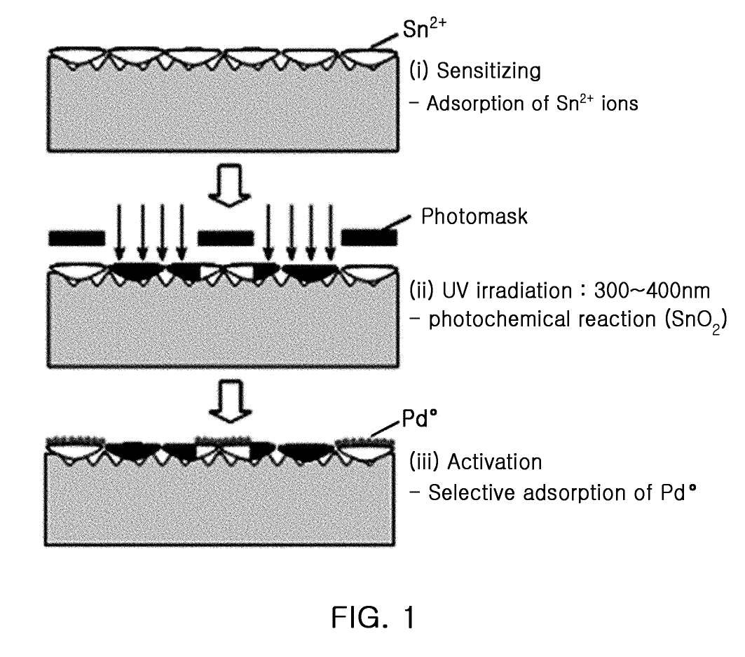

FIG. 1 shows a method of selectively adsorbing a precious metal on the surface of a polymer adsorbed with photosensitive metal ions according to an embodiment of the present invention. Hereinafter, the method of selectively adsorbing a precious metal on the surface of a polymer will be described in detailed steps with reference to FIG. 1.

First, the surface of a polymer adsorbed with photosensitive metal ions is masked with a photomask, and then the surface of the polymer is irradiated with a light source to oxidize the photosensitive metal ions which are on the non-masked surface of the polymer.

In one embodiment, the specific portion of the surface of the polymer adsorbed with photosensitive metal ions, that is, the portion of the surface of the polymer to be adsorbed with photosensitive metal ions, is masked with a photomask to block a light source, and the portion which is not blocked by the light source is irradiated with the light source to oxidize the photosensitive metal ions. The light source may be ultraviolet (UV) and have a wavelength of 200-450 nm, preferably, 300-420 nm, although not limited thereto. The wavelength of 200 nm or higher would provide less expensive solutions for the light source, and the wavelength of 450 nm or lower would provide faster oxidation of the photosensitive metal compound, hence faster processing. Further, the irradiation intensity of the light source is 10-30 mW/cm².

Second, the photosensitive metal ions which are not oxidized in the first step are reacted with a precious metal catalyst to adsorb the precious metal catalyst on the surface of the polymer.

In one embodiment, a solution containing the precious metal catalyst is brought into contact with the surface of the polymer, and thus the photosensitive metal ions which are not oxidized by blocking the light source using the photomask in the first step are reacted with the precious metal catalyst to adsorb the precious metal catalyst on the surface of the polymer. For convenience, this step is called an activation process. The activation process may be performed at a temperature of 20-50° C., preferably, 20-30° C. for 20 seconds to 5 minutes, preferably, 30 seconds to 2 minutes such that the precious metal catalyst is sufficiently adsorbed on the surface of the polymer.

When the polymer adsorbed with a precious metal catalyst, prepared using the above method, is used, a metal circuit pattern can be easily formed on the surface of the polymer by wet surface treatment such as electroless plating or the like. The wet surface treatment such as electroless plating or the like may be conducted using a method known in the related field. The polymer including the metal circuit pattern formed in this way can be easily used in automobiles, electronics, communications and semiconductors requiring micro-circuit boards because copper, nickel or the like adheres thinly and closely to the surface thereof.

Hereinafter, embodiments of the present invention will be described in more detail with reference to the following Examples. However, the scope of the present invention is not limited these examples.

### Example 1

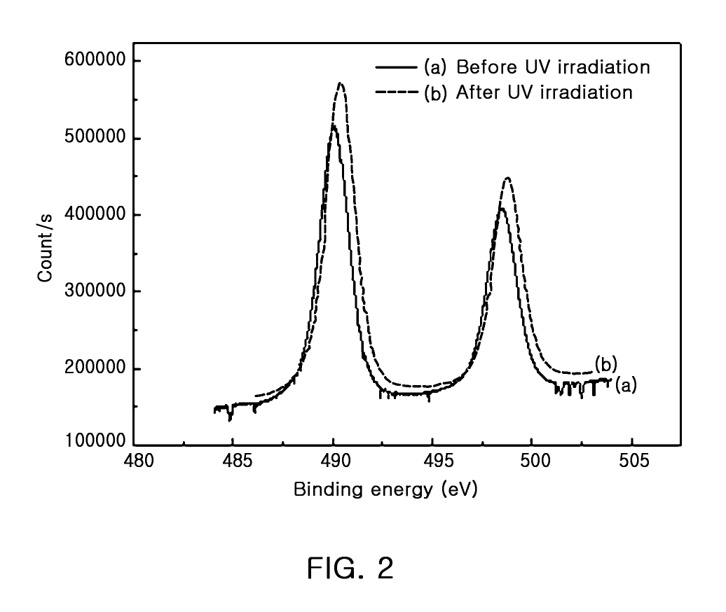

Polyimide (PI) or polyethylene terephthalate (PET), as a polymer, was immersed in a photosensitive metal ion-containing solution having the composition given in Table 1 below for 4-8 minutes, and then tin ions (Sn²⁺), which are photosensitive metal ions, were adsorbed on the surface of the polymer. Subsequently, a photomask was disposed on the surface of the polymer adsorbed with the tin ions (Sn²⁺), and the surface thereof was irradiated with ultraviolet (UV) light having a wavelength of 365 nm. The tin ions (Sn²⁺) which are on the UV-irradiated surface of the polymer were oxidized into tin ions (Sn4⁺) by a photochemical reaction. The changes of the tin ions depending on whether the photochemical reaction was conducted or not were analyzed using X-ray photoelectron spectroscopy (XPS), and the results thereof are shown in FIG. 2.

TABLE 1

| SnCl₂ | HCl |
|---|---|
| 0.3-0.6 mol/l | 0.08 mol/l |

Temperature: 18-25° C., treatment time: 4-8 minutes

### Example 2

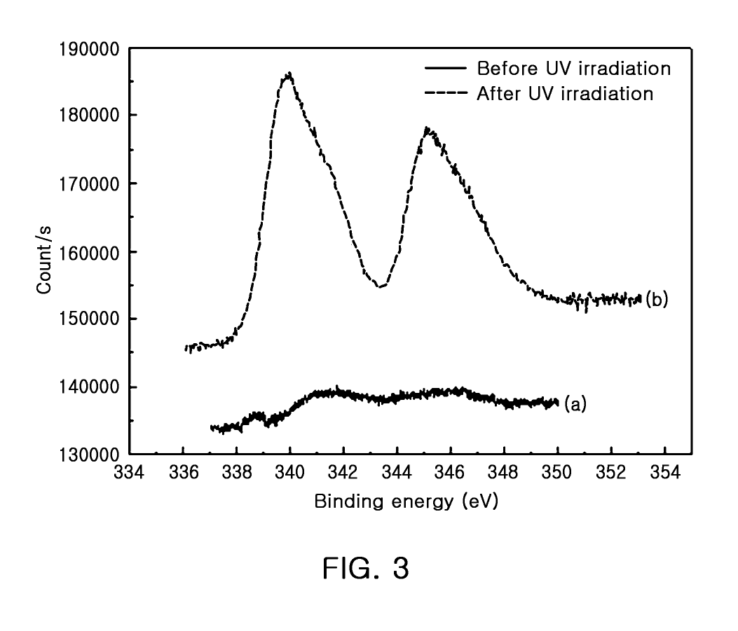

The surface of the polymer of Example 1 was immersed in a precious metal catalyst solution having the composition given in Table 2. Palladium ions (Pd²⁺) were reduced to palladium) (Pd^{o}) to be adsorbed on the surface of the polymer. The changes of the palladium ions depending on whether the photochemical reaction was conducted or not were analyzed using X-ray photoelectron spectroscopy (XPS), and the results thereof are shown in FIG. 3.

TABLE 2

| PdCl₂ | HCl |
|---|---|
| 0.03 mol/l | 0.02 mol/l |

Temperature: 18-25° C., treatment time: 30 seconds

The polymer adsorbed with a precious metal catalyst, prepared according to embodiments of the present invention, is advantageous in that various shapes of metal pattern layers can be simply and easily formed on the surface thereof, and a metal circuit layer made of copper, nickel or the like adheres closely to the surface thereof, and thus it can be easily used in automobiles, electronics, communications and semiconductors requiring micro-circuit boards.

What is claimed is:

1. A method of selectively depositing a precious metal over a polymeric surface, the method comprising:
providing a device comprising a polymeric substrate and photosensitive metal ions formed over the polymeric substrate;
projecting light beams from a light source toward the device through a patterned photo mask such that light beams reach an unmasked portion of the device while light beams do not reach a masked portion of the device, which selectively oxidizes photosensitive metal ions formed in the unmasked portion while photosensitive metal ions formed in the masked portion are not oxidized; and
subsequently contacting a solution containing a precious metal with the device, which selectively reacts with the non-oxidized photosensitive metal ions such that the precious metal is deposited onto the masked portion while not deposited onto the unmasked portion.

2. The method of claim 1, wherein providing device comprises:
contacting the polymeric substrate with a solution containing the photosensitive metal ions.

3. The method of claim 1, wherein the polymeric substrate comprises a film comprising at least one material selected from the group consisting of polyimide (PI), polyethylene terephthalate (PET), and aramid.

4. The method of claim 1, wherein the photosensitive metal ions comprise ions of at least one metal selected from the group consisting of titanium (Ti), molybdenum (Mo), tungsten (W), and tin (Sn).

5. The method of claim 1, wherein the light beams are ultraviolet light beams with wavelengths sufficient to cause oxidation of the photosensitive metal ions.

6. The method of claim 1, wherein the precious metal is at least one selected from the group consisting of silver (Ag), palladium (Pd), platinum (Pt), and gold (Au).

7. The method of claim 1, wherein contacting the solution with the device is performed at a temperature of about 20° C. to about 50° C.

8. The method of claim 1, wherein contacting the solution with the device is performed for a period from about 20 seconds to about 5 minutes.

9. A device produced from the method of claim 1.

10. A method of making a metallic circuit pattern over a polymeric substrate, comprising:
the method of claim 1 to provide an intermediate device comprising a polymeric substrate and a precious metal pattern selectively deposited over the polymeric substrate;
conducting electroless plating onto the intermediate device to provide a metallic circuit pattern over the polymeric substrate.

11. A device produced from the method of claim 10

12. A method of selectively adsorbing a precious metal catalyst on a polymer surface, comprising the steps of:
1) masking a surface of a polymer adsorbed with a photosensitive metal ions with a photo mask and then irradiating the surface of the polymer with a light source to oxidize photosensitive metal ions which are on the non-masked surface of the polymer; and
2) reacting the photosensitive metal ion not oxidized in step 1) with a precious metal catalyst to adsorb the precious metal catalyst on the surface of the polymer.

13. The method according to claim 12, wherein the polymer is any one selected from the group consisting of polyimide (PI), polyethylene terephthalate (PET), and aramid film.

14. The method according to claim 12, wherein the photosensitive ion is any one selected from the group consisting of titanium (Ti) ion, molybdenum (Mo) ion, tungsten (W) ion, and tin (Sn) ion.

15. The method according to claim 12, wherein the light source is an ultraviolet (UV) light source.

16. The method according to claim 12, wherein the ultraviolet (UV) light source has a wavelength of 200-450 nm.

17. The method according to claim 12, wherein the precious metal catalyst is any one selected from the group consisting of silver (Ag), palladium (Pd), platinum (Pt), and gold (Au).

18. The method according to claim 12, wherein the step 2) is performed at a temperature of 20-50° C. for 20 seconds to 5 minutes.
